(19) United States
(12) Patent Application Publication
(10) Pub. No.: US 2025/0253825 A1
(43) Pub. Date: Aug. 7, 2025

(54) BULK ACOUSTIC WAVE RESONATOR EXHIBITING SECOND OVERTONE STRESS MODE

(71) Applicant: SKYWORKS SOLUTIONS, INC., Irvine, CA (US)

(72) Inventor: Ahmed E. Hassanien, Savoy, IL (US)

(21) Appl. No.: 19/038,871

(22) Filed: Jan. 28, 2025

Related U.S. Application Data
(60) Provisional application No. 63/548,968, filed on Feb. 2, 2024.

(51) Int. Cl. H03H 9/02; H03H 9/13; H03H 9/17; H03H 9/54

(52) U.S. Cl. CPC H03H 9/02102; H03H 9/13; H03H 9/174; H03H 9/176; H03H 9/547

(57) ABSTRACT

Aspects and embodiments disclosed herein include a bulk acoustic wave resonator comprising a pair of electrodes, a temperature compensation layer located adjacent to one of the electrodes of the pair of electrodes, and a piezoelectric layer situated between the pair of electrodes and the temperature compensation layer such that a polarity flipping point of a second overtone stress mode shape is located at the electrode adjacent to the temperature compensation layer.

### CROSS-REFERENCE TO RELATED APPLICATIONS

This application claims priority under 35 U.S.C. § 119(e) to U.S. Provisional Patent Application Ser. No. 63/548,968, titled “BULK ACOUSTIC WAVE RESONATOR EXHIBITING SECOND OVERTONE STRESS MODE,” filed Feb. 2, 2024, the entire content of which is incorporated by reference herein for all purposes.

### BACKGROUND

### Field

Aspects and embodiments disclosed herein relate to a bulk acoustic wave (BAW) resonator used in a bulk acoustic wave device.

### Description of Related Technology

Acoustic wave devices, for example, surface acoustic wave (SAW) and bulk acoustic wave (BAW) devices may be utilized as components of filters in radio frequency electronic systems. For instance, filters in a radio frequency front end of a mobile telephone can include acoustic wave filters. A BAW device is an electromechanical device that generates a standing acoustic wave in the bulk of a piezoelectric material using an electrical signal.

The two main types of acoustic wave filters, i.e. BAW and SAW filters, convert electrical and acoustic signals using a piezoelectric substrate. BAW filters direct the signal energy through the bulk of the substrate, while SAW filters direct the signal energy along the surface of the substrate. Though this distinction may seem simple at first, the reality is that these different approaches result in significant differences in performance and frequency capabilities.

SAW filters are generally less complex to design and fabricate, as the fabrication process mainly consists of developing surface structures. Conversely, BAW filters are fabricated with precise control of substrate thickness and layered structures, such as acoustic reflectors precisely spaced in a stack.

However, the relative dimensions and physics associated with BAW filters allow them to be designed for even higher frequency operation and higher quality factor Q performance than is typically possible with SAW technology; this is due to the physical limitations of electroacoustic transduction at the surface. Moreover, BAW filters can be fabricated on technology compatible with standard IC processing systems and typically demonstrate higher power handling capability. BAW filters also exhibit lower frequency drift with temperature than SAW filters, though there are SAW filter technologies that incorporate temperature compensation design features or are otherwise fabricated in such a way as to minimize temperature sensitivity.

In general, SAW filters can be practically fabricated to operate at frequencies up to 2,000 MHz or 2,500 MHz. In comparison, it is possible to manufacture BAW filters that operate at frequencies up to 10 GHz or even beyond.

However, moving towards high frequency bands often involves fabricating bulk acoustic wave devices with very thin piezoelectric material layer stacks, which may result in reduced ruggedness and power handling and increased process variation. Further, the quality factor of a high frequency bulk acoustic wave device may be diminished due to reduced crystallinity in the piezoelectric material layer stack. Moreover the thin stack leads to an increased electrode resistance.

### SUMMARY

The innovations described in the claims each have several aspects, no single one of which is solely responsible for its desirable attributes. Without limiting the scope of the claims, some prominent features of this disclosure will now be briefly described.

According to an aspect of this disclosure, a bulk acoustic wave resonator includes a pair of electrodes, a temperature compensation layer located adjacent to one of the electrodes of the pair of electrodes, and a piezoelectric layer situated between the pair of electrodes and the temperature compensation layer such that a polarity flipping point of a 2^{nd} overtone stress mode shape is located at the electrode adjacent to the temperature compensation layer.

In some embodiments, the pair of electrodes include metal electrodes. In several embodiments, the metal electrodes include ruthenium electrodes. In a number of embodiments, the pair of electrodes include a top electrode on top of the piezoelectric layer and a bottom electrode beneath the piezoelectric layer.

In various embodiments, the temperature compensation layer is situated adjacent to the top electrode of the pair of electrodes.

In some embodiments, the temperature compensation layer forms a passivation layer.

In a few embodiments, the piezoelectric layer includes a piezoelectric material. The piezoelectric material may in a number of embodiments include aluminum nitride. In several embodiments, the aluminum nitride is doped with scandium. In other embodiments, the piezoelectric material includes zinc oxide.

In some embodiments, the temperature compensation layer includes a silicon dioxide layer.

In a number of embodiments, the BAW resonator further comprises a thin adhesion layer between the temperature compensation layer and the top electrode of the pair of electrodes.

In various embodiments, the bottom electrode of the pair of electrodes is located on a bottom seed layer. In some embodiments, the bottom seed layer is located on a micro-machined layer.

In a few embodiments, the BAW resonator further includes a notch filter connected to an output electrode of the pair of electrodes. In various embodiments, the notch filter is configured to filter the fundamental frequency of the BAW resonator.

In a number of embodiments, the output electrode is formed by a top electrode on top of the piezoelectric layer or a bottom electrode beneath the piezoelectric layer.

According to another aspect of this disclosure, a film bulk acoustic wave resonator includes a pair of electrodes, a temperature compensation layer located adjacent to one of the electrodes of the pair of electrodes, a membrane including a piezoelectric layer situated between the pair of electrodes and the temperature compensation layer such that a polarity flipping point of a 2^{nd} overtone stress mode shape is located at the electrode adjacent to the temperature compensation layer, and an air cavity located under the membrane.

According to another aspect of this disclosure, a solidly mounted resonator (SMR) includes a pair of electrodes, a temperature compensation layer located adjacent to one of the electrodes of the pair of electrodes, a layer stack including a piezoelectric layer situated between the pair of electrodes and the temperature compensation layer such that a polarity flipping point of a 2^{nd} overtone stress mode shape is located at the electrode adjacent to the temperature compensation layer, and acoustic reflectors located under the layer stack.

According to another aspect of this disclosure, an acoustic wave filter includes at least one bulk acoustic wave (BAW) resonator, the BAW resonator including a pair of electrodes, a temperature compensation layer located adjacent to one of the electrodes of the pair of electrodes, and a piezoelectric layer situated between the pair of electrodes and the temperature compensation layer such that a polarity flipping point of a 2^{nd} overtone stress mode shape is located at the electrode adjacent to the temperature compensation layer.

In some embodiments, the acoustic wave filter is a band pass filter or a band stop filter. In various embodiments, the acoustic wave filter has a center frequency corresponding to the frequency of the 2^{nd} overtone mode.

According to another aspect of this disclosure, a wireless communication device includes at least one acoustic wave filter having at least one bulk acoustic wave (BAW) resonator, the BAW resonator including a pair of electrodes, a temperature compensation layer located adjacent to one of the electrodes of the pair of electrodes, and a piezoelectric layer situated between the pair of electrodes and the temperature compensation layer such that a polarity flipping point of a 2^{nd} overtone stress mode shape is located at the electrode adjacent to the temperature compensation layer.

In some embodiments, the acoustic wave filter has a center frequency corresponding to the frequency of the second overtone mode.

According to another aspect of this disclosure, a method for filtering an electrical input signal includes the steps of supplying an electrical input signal to an input electrode of a bulk acoustic wave (BAW) resonator, the BAW resonator including the input electrode, an output electrode, a temperature compensation layer situated adjacent to the input electrode or the output electrode, and a piezoelectric layer situated between the input electrode and an output electrode such that a polarity flipping point of a 2nd overtone stress mode shape is located at the electrode adjacent to the temperature compensation layer; and outputting a filtered electrical output signal at the output electrode.

In a few embodiments, outputting the filtered electrical output signal includes supplying the filtered electrical output signal to a notch filter and filtering the fundamental frequency of the BAW resonator.

### BRIEF DESCRIPTION OF THE DRAWINGS

Embodiments of this disclosure will now be described, by way of non limiting example, with reference to the accompanying drawings.

FIG. 1 illustrates the fundamental frequencies and overtones within a layer;

FIGS. 2 and 3 illustrate possible embodiments of a bulk acoustic wave resonator according to example embodiments;

FIGS. 4 and 5 show diagrams to illustrate the functional behavior of a bulk acoustic wave resonator stack with varying layer thicknesses for different operation frequencies;

FIG. 6 illustrates a frequency response of a bulk acoustic wave resonator according to another example embodiment;

FIG. 7 is a block diagram of an exemplary front-end module including filters with bulk acoustic wave resonators according to another example embodiment; and

FIG. 8 is a block diagram of an exemplary wireless device including filters with bulk acoustic wave resonators according to another example embodiment.

### DETAILED DESCRIPTION

The following description presents various descriptions of specific embodiments.

The innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

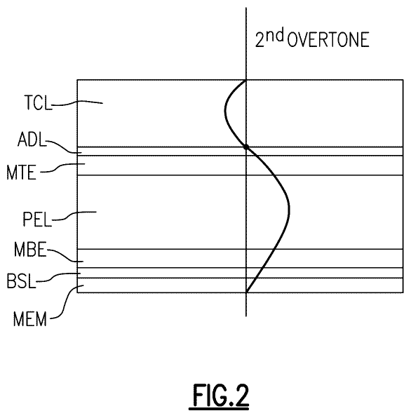

FIGS. 2 and 3 illustrate a portion of an example of a bulk acoustic wave resonator in which acoustic waves are generated during operation. As illustrated in the embodiments of FIGS. 2 and 3, a bulk acoustic wave resonator may include a piezoelectric layer PEL being situated between a pair of electrodes including a bottom electrode (MBE) and a top electrode (MTE). A temperature compensation layer TCL is situated adjacent to one of the electrodes MBE and MTE of the pair of electrodes. The temperature compensation layer TCL is configured such that a polarity flipping point PFP of a 2^{nd} overtone stress mode shape is located at the electrode (for example, the top electrode MTE in FIG. 2 or the bottom electrode MBE in FIG. 3) adjacent to the temperature compensation layer TCL.

The bulk acoustic wave resonator BAWR as shown in the embodiments of FIGS. 2 and 3 operates based on the propagation of acoustic waves through a piezoelectric material of the piezoelectric layer PEL. The bulk acoustic wave resonator BAWR can be used in radio frequency (RF) and microwave applications for signal filtering and frequency selection.

One idea underlying some examples of this disclosure is to thicken the stack of the bulk acoustic wave resonator BAWR by operating at the 2^{nd} overtone instead of the fundamental tone, allowing the stack to become approximately twice as thick as conventionally. This results in better manufacturability and ruggedness. In some implementations, the thickness of the stack can be increased by increasing the thickness of the temperature compensation layer TCL that is deposited on top of (FIG. 2) or below (FIG. 3) the piezoelectric layer PEL sandwiched between the electrodes MBE and MTE.

In the bulk acoustic wave resonator BAWR the provided electromechanical coupling is an important parameter that influences the performance of the resonator. Electromechanical coupling is a measure of the efficiency with which electrical energy is converted into mechanical vibrations (and vice versa) within the piezoelectric material of the piezoelectric layer PEL.

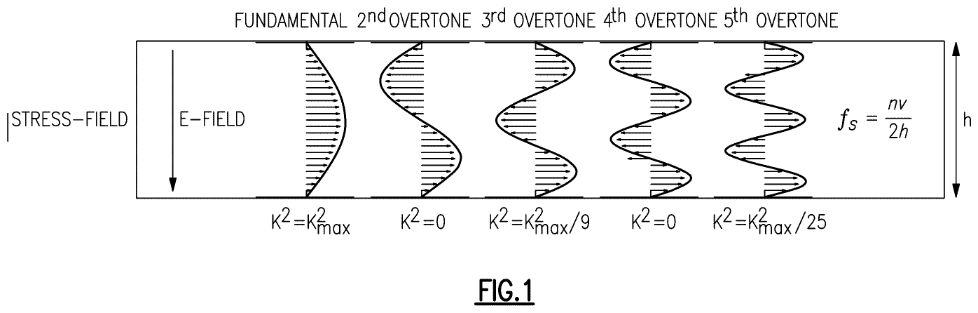

FIG. 1 illustrates a fundamental frequency and overtones in a layer with thickness h. Higher overtones comprise higher operating frequencies with a lower coupling compared to the fundamental frequency (˜1/n², with n being the mode order). The bulk acoustic wave resonator BAWR of FIGS. 2 and 3 utilizes the 2^{nd} overtone for coupling.

The fundamental resonance frequency f_{R} of a BAW resonator stack refers to the lowest resonant frequency at which the resonator exhibits a significant response. In the context of BAW filters, the fundamental frequency corresponds to the primary vibrational mode of the piezoelectric material within the stack. In a single piezoelectric layer stack the fundamental frequency f_{R} is defined by:

$${f}_{R} = v / 2 h$$

with v being the velocity of the waves in the piezoelectric material and h being the thickness of the piezoelectric layer PEL.

Overtones refer to higher harmonic resonances in the BAW filter stack. Each overtone shown in FIG. 1 corresponds to a higher-order vibrational mode of the piezoelectric material. The presence of overtones results in multiple resonant frequencies within the BAW resonator stack. The spacing between these resonant frequencies is influenced by factors such as the thickness of the piezoelectric layer PEL and the specific design of the resonator.

The thickness of the stack can be optimized to achieve different objectives including temperature compensation, maximizing the electromechanical coupling and targeting a specific frequency at the 2^{nd} overtone. The stack can achieve higher coupling for specific frequency bands by using scandium doping.

The stack of the resonator BAWR is designed to achieve sufficient temperature compensation while at the same time avoiding excessive loss of electromechanical coupling capacity.

The bulk acoustic wave resonator BAWR is configured to operate at the 2^{nd} overtone while the temperature compensation layer TCL is not located between the electrodes but on top or beneath one of the electrodes. This results in an improved electromechanical coupling and less resonator area due to higher capacitance. Since the temperature compensation layer TCL is not located between the electrodes MBE, MTE there is no electric field E in the temperature compensation layer TCL so that an unwanted reduction of the electromechanical coupling due to an applied electrical field is avoided.

In some implementations, the pair of electrodes MBE and MTE include metal electrodes. The metal electrode pair include a top metal electrode MTE and a bottom metal electrode MBE. The pair of electrodes includes a top electrode MTE provided on top of the piezoelectric layer PEL and a bottom electrode MBE provided beneath the piezoelectric layer PEL. In some implementations, the metal electrodes MTE and MBE may be ruthenium (Ru) electrodes.

The piezoelectric layer PEL is sandwiched between the top electrode MTE and the bottom electrode MBE. Piezoelectric materials can convert electrical energy into mechanical vibrations and vice versa. When an electrical signal is applied to the piezoelectric material, it generates mechanical vibrations or acoustic waves. When an electrical signal is applied to the input electrode, it creates an electric field across the piezoelectric material of the piezoelectric layer PEL. This electric field causes the material to deform, generating mechanical vibrations or acoustic waves in the form of bulk acoustic waves.

These acoustic waves propagate through the piezoelectric crystal. The frequency of the acoustic waves is determined by the physical dimensions of the piezoelectric material and the transducer configuration. The design of the bulk acoustic wave resonator BAWR is such that only specific frequencies of acoustic waves resonate and pass through the crystal efficiently. The resonance frequency is determined by the thickness and material properties of the stack, in particular the piezoelectric layer PEL. The bulk acoustic wave resonator BAWR is designed to transmit or reflect specific frequency components of the input signal based on the resonance characteristics of the piezoelectric layer PEL.

Unwanted frequencies are reflected or absorbed by the piezoelectric layer PEL, while the desired frequencies are transmitted to the output electrode. The output electrode detects the transmitted acoustic waves, and the mechanical vibrations are converted back into an electrical signal. The output signal contains only the desired frequency components that have passed through the bulk acoustic wave resonator BAWR. The filter characteristics of the bulk acoustic wave resonator BAWR, including bandwidth, center frequency, and selectivity, are determined by the physical properties of the piezoelectric material and the transducer design.

Without being bound by any specific theory or explanation, one approach to the piezoelectric effect involves the displacement of atoms in a non-centrosymmetric crystal lattice under applied stress. The deformation of the crystal structure leads to the buildup of charges on its surfaces, i.e., voltage generation. The process can also be reversed so that applied external voltage results in deformation. In a quasi-static method, also known as the Berlincourt method, the piezoelectric coefficient can be determined by measurement of the voltage generated in the sample under the influence of pressure exerted by a vibrating lever, or alternatively by measuring the lever deflection caused by deformation of the sample under an applied electric field.

The electromechanical coupling factor, k, is an indicator of the effectiveness with which a piezoelectric material converts electrical energy into mechanical energy, or converts mechanical energy into electrical energy.

‘The electromechanical coupling factor k is related to the conversion rate between electrical energy and mechanical energy. K² is the ratio of stored mechanical energy to input electrical energy, or the ratio of stored electrical energy to input mechanical energy. The term “coupling coefficient” refers to a dimensionless parameter that characterizes the resonators effective electromechanical coupling coefficient.

For a simplified one dimensional case with a stack including two layers L1, L2 the coupling coefficient k can be approximated by:

$${K}^{2} = \frac{8}{{π}^{2}} \frac{{( {d}_{1} {E}_{1} {T}_{1} {h}_{1} + {d}_{2} {E}_{2} {T}_{2} {h}_{2} )}^{2}}{( {ε}_{1} {E}_{1}^{2} {h}_{1} + {ε}_{2} {E}_{2}^{2} {h}_{2} ) ( {S}_{1} {T}_{1}^{2} {h}_{1} + {S}_{2} {T}_{2}^{2} {h}_{2} )}$$

wherein E is the electric field strength, S is the compliance coefficient, T is the mechanical stress, h is the layer thickness, d is the piezoelectric coefficient and ε is the permittivity.

To maximize the electromechanical coupling at the 2^{nd} overtone one can improve the piezoelectricity and/or minimize the electric field E in the non-piezoelectric layers and/or reduce the elastic energy in all layers of the stack.

In a possible implementation, the piezoelectric layer PEL of the bulk acoustic wave resonator BAWR has a thickness of about 410 nm provided between a pair of metal electrodes MBE and MTE, each of the electrodes having a thickness of about 85 nm. The temperature compensation layer TCL may be located adjacent to the top electrode MTE of the pair of electrodes.

The temperature compensation layer TCL may form a passivation layer. The temperature compensation layer TCL can include a silicon dioxide (SiO₂) layer. Temperature compensation (TC) in bulk acoustic wave (BAW) resonators is desired for maintaining a stable performance over a range of temperatures. The piezoelectric properties of the material used in the piezoelectric layer PEL, particularly the resonant frequency, can be sensitive to temperature variations.

The piezoelectric layer PEL includes a piezoelectric material, for example, aluminum nitride (AlN) or zinc oxide (ZnO). AlN may be doped in some implementations with scandium.

In some implementations, a thin adhesion layer ADL may be provided between the temperature compensation layer TCL and the top electrode MTE of said pair of electrodes. The adhesion layer ADL may, for example, have a thickness of about 10 nm.

In some implementations, the bottom electrode MBE is located on a bottom seed layer BSL. The bottom seed layer BSL may, for example, have a thickness of about 40 nm. The bottom seed layer BSL may be located on a micro-machined (MEM) layer having a thickness of, for example, about 50 nm. The MEM layer includes the micro-machined structures that form the piezoelectric material and electrodes. This layer may be designed using MEMS fabrication techniques, allowing for precise control over the dimensions and properties of the piezoelectric elements.

In some implementations, a notch filter NFIL may be connected to an output electrode of the pair of electrodes. The notch filter NFIL may be configured to filter the fundamental frequency of the bulk acoustic wave resonator BAWR. In some implementations, the output electrode is formed by the top electrode MTE provided on top of the piezoelectric layer PEL. Alternatively, the output electrode may be formed by the bottom electrode MBE provided beneath the piezoelectric layer PEL.

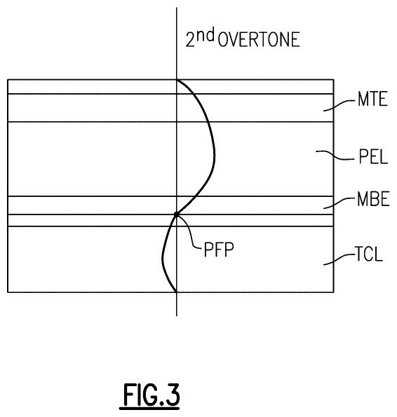

FIG. 4 shows a diagram of the electromechanical coupling behavior of a stack comprising a piezoelectric layer PEL made of aluminum nitride (AlN) and comprising a temperature compensation layer TCL made of silicon dioxide (SiO₂) for different operation frequencies f ranging from 5.4 GHz to 6 GHz. The thickness of the piezoelectric layer PEL ranges between about 380 nm and about 430 nm. The thickness of the temperature compensation layer TCL ranges between about 380 nm and about 480 nm. For example, for an operation frequency of 5.9 GHz, the thickness of the piezoelectric layer PEL is designed to amount to 410 nm and the thickness of the temperature compensation layer TCL is designed to amount to 380 nm as illustrated in the example diagram of FIG. 4.

FIG. 5 illustrates the sensitivity of the bulk acoustic wave resonator stack against temperature changes, measured in ppm (parts per million) per degrees Kelvin temperature.

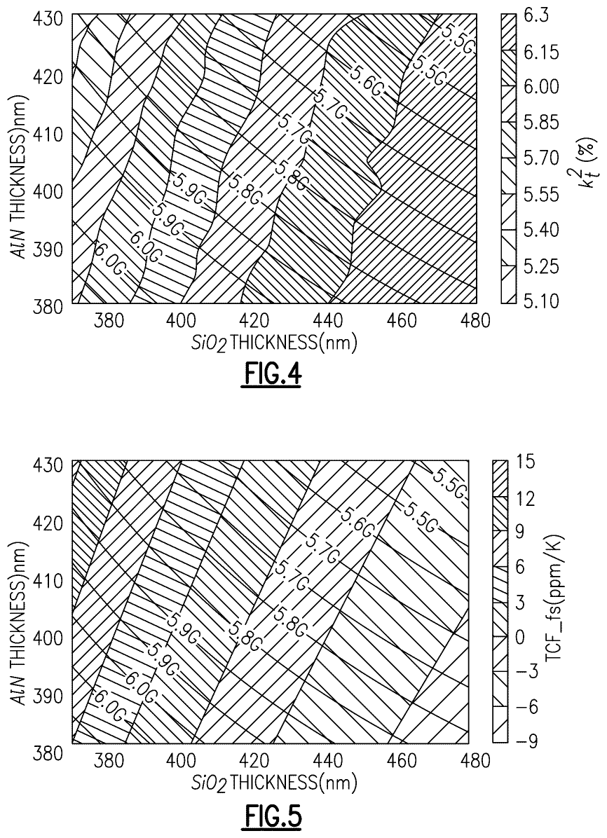

FIG. 6 illustrates the frequency response behavior (admittance) of some embodiments of the bulk acoustic wave resonator BAWR according to some examples of the present disclosure. There is a resonance at the fundamental frequency and at the 2^{nd} overtone at 5.87 GHz. The 2^{nd} overtone is utilized as the operation frequency while the fundamental frequency is suppressed, e.g. by a notch filter provided at the output of the BAW resonator.

A film bulk acoustic wave resonator may include a membrane or stack including a piezoelectric layer PEL being situated between a pair of electrodes MBE, MTE and a temperature compensation layer TCL being situated adjacent to one of the electrodes of the pair of electrodes and being configured such that a polarity flipping point of a 2^{nd} overtone stress mode shape is located at the electrode adjacent to the temperature compensation layer TCL. The film bulk acoustic wave resonator includes a cavity situated under the membrane.

The film bulk acoustic wave resonator is a form of a bulk acoustic wave resonator BAWR that generally includes a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A film bulk acoustic wave resonator exhibits a frequency response to applied signals with a resonance peak determined by a thickness of the film of piezoelectric material. Ideally, the only acoustic wave that is generated in a film bulk acoustic wave resonator is a main acoustic wave that travels through the film of piezoelectric material in a direction perpendicular to layers of conducting material forming the top and bottom electrodes.

A solidly mounted resonator (SMR) may include a stack including a piezoelectric layer PEL being situated between a pair of electrodes and a temperature compensation layer TCL being situated adjacent to one of the electrodes of the pair of electrodes and being configured such that a polarity flipping point of a 2^{nd} overtone stress mode shape is located at the electrode adjacent to the temperature compensation layer TCL. The SMR includes acoustic reflectors situated under the stack.

The SMR is constructed by directly attaching a piezoelectric resonator to a substrate without an air gap. This design enhances the energy transfer efficiency between the piezoelectric material and the substrate. The solidly mounted resonator exhibits a high stability and a low insertion loss. In the SMR structure, a “mirror” under the bottom electrode reflects acoustic waves. By reflecting acoustic waves back to the piezoelectric film, they play a role in limiting energy dissipation.

An acoustic wave filter includes at least one bulk acoustic wave resonator BAWR including a piezoelectric layer PEL being situated between a pair of electrodes and a temperature compensation layer TCL being situated adjacent to one of the electrodes of the pair of electrodes and being configured such that a polarity flipping point of a 2^{nd} overtone stress mode shape is located at the electrode adjacent to the temperature compensation layer TCL. The acoustic wave filter may, for example, be employed as a band pass filter or a band stop filter. The acoustic wave filter may thus have a center frequency corresponding to the frequency of the 2^{nd} overtone mode.

A wireless communication device includes at least one acoustic wave filter having at least one bulk acoustic wave resonator BAWR including a piezoelectric layer PEL being situated between a pair of electrodes and a temperature compensation layer TCL being situated adjacent to one of the electrodes of the pair of electrodes and being configured such that a polarity flipping point of a 2nd overtone stress mode shape is located at the electrode adjacent to the temperature compensation layer TCL.

A method for filtering an electrical input signal involves the steps of supplying an electrical input signal to an input electrode of a bulk acoustic wave (BAW) resonator, the BAW resonator including the input electrode, an output electrode, a temperature compensation layer situated adjacent to the input electrode or the output electrode, and a piezoelectric layer situated between the input electrode and an output electrode such that a polarity flipping point of a 2^{nd} overtone stress mode shape is located at the electrode adjacent to the temperature compensation layer; and outputting a filtered electrical output signal at the output electrode. The filtered electrical output signal may be supplied to a notch filter NFIL which filters the fundamental frequency of the bulk acoustic wave resonator BAWR.

Examples of bulk acoustic wave resonators BAWR as disclosed herein may be combined to form a ladder filter for a radio frequency device, for example, a cellular phone.

The bulk acoustic wave resonators may be any of film bulk acoustic wave resonators, Lamb wave resonators, solidly mounted resonators, or any combination of these types of resonators. A ladder filter may function as a band pass filter exhibiting low attenuation for signals within a certain frequency range, referred to as the passband of the filter, while exhibiting high attenuation for signals with frequencies above and below the passband, referred to as the stop bands of the filter.

Various examples and embodiments of the acoustic wave filters and duplexers including same as disclosed herein can be used in a wide variety of electronic devices, such as RF front-end modules and communication devices.

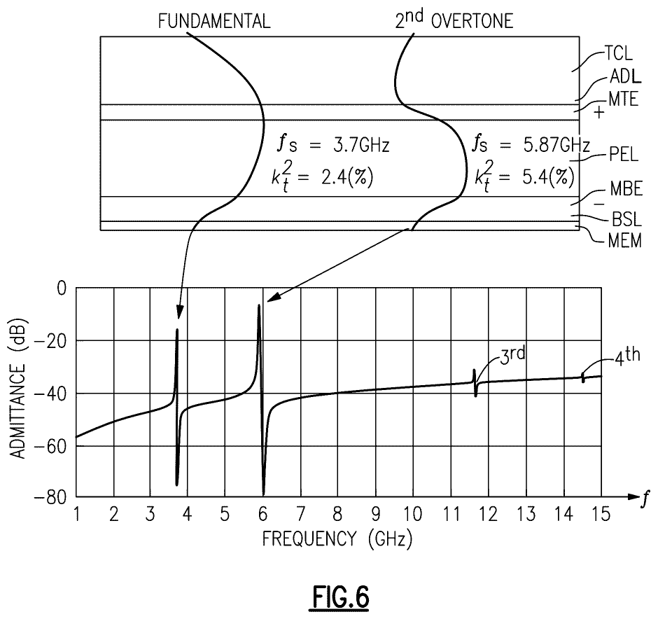

Referring to FIG. 7 there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmission filters 512 connected between the input node 504 and the common node 502, and one or more reception filters 514 connected between the common node 502 and the output node 506. The passband(s) of the transmission filter (s) are different from the passband(s) of the reception filters.

Embodiments of the bulk acoustic wave resonator BAWR disclosed herein can be used to form the transmission filter(s) 512 and/or the reception filter(s) 514. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 7, however, in other embodiments these components may be integrated into a common transceiver circuit or module. As will be appreciated by those skilled in the art, the front-end module 500 may include other components that are not illustrated in FIG. 7 including, but not limited to, switches, electromagnetic couplers, amplifiers, processors, and the like.

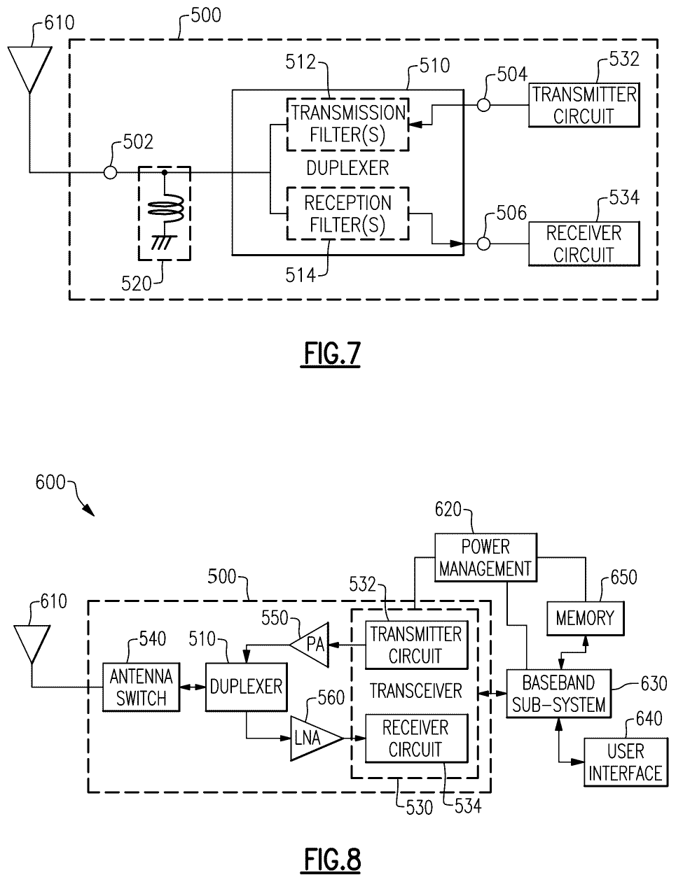

FIG. 8 is a block diagram of one example of a wireless device 600 including the antenna duplexer 510 shown in FIG. 7. The wireless device 600 can be a cellular phone, smartphone, tablet, modem, communication network or any other portable or non-portable device configured for voice or data communication. The wireless device 600 can receive and transmit signals from the antenna 610.

The wireless device includes an embodiment of a front-end module 500 similar to that discussed above with reference to FIG. 7. The front-end module 500 includes the duplexer 510, as discussed above. In the example shown in FIG. 8 the front-end module 500 further includes an antenna switch 540, which can be configured to switch between different frequency bands or modes, such as transmit and receive modes, for example. In the example illustrated in FIG. 8, the antenna switch 540 is positioned between the duplexer 510 and the antenna 610, however, in other examples the duplexer 510 can be positioned between the antenna switch 540 and the antenna 610. In other examples the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 8.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 8 the front-end module 500 may further include a low noise amplifier module 560, which amplifies received signals from the antenna 610 and provides the amplified signals to the receiver circuit 534 of the transceiver 530.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bulk acoustic wave (BAW) resonator comprising:
a pair of electrodes;
a temperature compensation layer located adjacent to one of the electrodes of the pair of electrodes; and
a piezoelectric layer situated between the pair of electrodes and the temperature compensation layer such that a polarity flipping point of a second overtone stress mode shape is located at the electrode adjacent to the temperature compensation layer.

2. The BAW resonator according to claim 1 wherein the electrodes of the pair of electrodes include metal electrodes.

3. The BAW resonator according to claim 2 wherein the metal electrodes include ruthenium electrodes.

4. The BAW resonator according to claim 1 wherein the pair of electrodes include a top electrode on top of the piezoelectric layer and a bottom electrode beneath the piezoelectric layer.

5. The BAW resonator according to claim 4 wherein the temperature compensation layer is situated adjacent to the top electrode of the pair of electrodes.

6. The BAW resonator according to claim 5 wherein the temperature compensation layer forms a passivation layer.

7. The BAW resonator according to claim 1 wherein the piezoelectric layer includes a piezoelectric material.

8. The BAW resonator according to claim 7 wherein the piezoelectric material includes aluminum nitride.

9. The BAW resonator according to claim 8 wherein the aluminum nitride is doped with scandium.

10. The BAW resonator according to claim 7 wherein the piezoelectric material includes zinc oxide.

11. The BAW resonator according to claim 1 wherein the temperature compensation layer comprises a silicon dioxide layer.

12. The BAW resonator according to claim 4 further comprising an adhesion layer between the temperature compensation layer and the top electrode of the pair of electrodes.

13. The BAW resonator according to claim 4 wherein the bottom electrode of the pair of electrodes is located on a bottom seed layer.

14. The BAW resonator according to claim 13 wherein the bottom seed layer is located on a micro-machined (MEM) layer.

15. The BAW resonator according to claim 1 further comprising a notch filter connected to an output electrode of the pair of electrodes.

16. The BAW resonator according to claim 15 wherein the notch filter is configured to filter the fundamental frequency of the BAW resonator.

17. The BAW resonator according to claim 15 wherein the output electrode is formed by a top electrode on top of the piezoelectric layer or a bottom electrode beneath the piezoelectric layer.

18. A film bulk acoustic wave resonator comprising:
a pair of electrodes;
a temperature compensation layer located adjacent to one of the electrodes of the pair of electrodes;
a membrane including a piezoelectric layer situated between the pair of electrodes and the temperature compensation layer such that a polarity flipping point of a second overtone stress mode shape is located at the electrode adjacent to the temperature compensation layer; and
an air cavity located under the membrane.

19. A wireless communication device comprising at least one acoustic wave filter having at least one bulk acoustic wave (BAW) resonator, the BAW resonator including a pair of electrodes, a temperature compensation layer located adjacent to one of the electrodes of the pair of electrodes, and a piezoelectric layer situated between the pair of electrodes and the temperature compensation layer such that a polarity flipping point of a second overtone stress mode shape is located at the electrode adjacent to the temperature compensation layer.

20. The wireless communication device of claim 19 wherein the acoustic wave filter has a center frequency corresponding to the frequency of the second overtone mode.
